(19) United States
(12) Patent Application Publication
(10) Pub. No.: US 2026/0009860 A1
(43) Pub. Date: Jan. 8, 2026

(54) Estimation of the Degradation of Batteries in Electric Vehicles

(71) Applicant: Vitesco Technologies USA, LLC, Auburn Hills, MI (US)

(72) Inventor: Jose Francisco Herrera Santos, Zapopan (MX)

(73) Assignee: Vitesco Technologies USA, LLC, Auburn Hills, MI (US)

(21) Appl. No.: 18/762,084

(22) Filed: Jul. 2, 2024

(51) Int. Cl. G01R 31/392; G01R 31/3835; G01R 31/389

(52) U.S. Cl. CPC G01R 31/392; G01R 31/3835; G01R 31/389

(57) ABSTRACT

A system and method monitor a state of health (SOH) of a battery. The battery has a voltage (V_{b}) and an internal series resistance (R_{b}). The system includes a capacitor and employs a high ohmic load during a capacitor pre-charging stage to control current inrush, with the pre-charging stage being used to measure the battery voltage. The system also employs a low ohmic load during a second stage that completes charging of the capacitor, with the second stage being used to estimate any change in the internal resistance. Switches interchange the two ohmic loads. A measured delta Vs is compared to a delta Vs stored in memory that defines a historical voltage value of a healthy battery. A change in V_{b} and/or R_{b} is identified, thus identifying a SOH of the battery as degraded when there is a difference between the measured delta Vs and the stored delta Vs.

### FIELD

This invention relates to batteries of vehicles including non-electric, electric and hybrid vehicles and, more particularly, to a system and method of monitoring the state of health (SOH) of one or more batteries to identify degradation over time.

### BACKGROUND

Conventional battery management systems for monitoring the SOH of batteries include the use of, for example: a sensing unit to measure temperature and battery current; use of acquired terminal current and terminal voltage; a microprocessor to initiate and shape a waveform which is sent to the battery and for sampling a returning waveform from the battery to obtain operating characteristics of the battery from the amplitude of the returning waveform; or the use of circuitry to detect and measure the battery's dynamic resistance through the use of an oscillator signal. Although these systems may be capable of monitoring battery SOH, improvement in monitoring battery SOH is needed.

There is a need to provide a system and method of monitoring the state of health (SOH) of one or more batteries based on measuring the battery voltage and its internal resistance and then comparing them against historical measurements to identify battery degradation.

### SUMMARY

An objective of the invention is to fulfill the need referred to above. In accordance with the principles of an embodiment, this objective is achieved by a method of determining a state of health (SOH) of at last one battery. The at least one battery has a battery voltage (V_{b}) and an internal resistance (R_{b}) with a first switch between the battery and circuits to be supplied with the at least one battery voltage (V_{b}). The method provides a sensing circuit electrically connected between the at least one battery and the first switch. The sensing circuit includes a first resistor having a value measured in Ω, and an associated second switch for controlling current through the first resistor; a second resistor having a value measured mΩ so as to be less than that of the first resistor, and an associated third switch for controlling current through the second resistor; a capacitor selectively electrically connectable between the first and second resistors via the first and second switches, respectively; a voltage node, and a voltage divider circuit configured to reduce voltage of the capacitor prior to reaching the voltage node. The method ensures that the first switch and third switch are open, and that the second switch is closed to define a pre-charging stage of the capacitor to charge the capacitor to a voltage substantially near the battery voltage V_{b}, while controlling inrush current. At the end of the pre-charging stage, the method obtains voltage value Vs1 associated with the voltage node. After the pre-charging stage, the method ensures that the first switch and the second switch are open, and that the third switch is closed to define second charging stage where the capacitor is charged completely. After a fixed time interval during the second charging stage, the method obtains voltage value Vs2 associated with the voltage node. A measured delta Vs (Vs2−Vs1) is compared to a delta Vs that defines a stored historical voltage value of a healthy battery. The method identifies a change in V_{b} and/or R_{b} when there is a difference between the measured delta Vs and the stored delta Vs and thus identifies a SOH of the at least one battery as degraded.

In accordance with another aspect of an embodiment, a system is provided to monitor a state of health (SOH) of at least one battery. The at least one battery has a battery voltage (V_{b}) and an internal resistance (R_{b}) with a first switch between the at least one battery and circuits to be supplied with the battery voltage (V_{b}). The system includes a sensing circuit between the at least one battery and the first switch. The sensing circuit includes a first resistor having a value measured in Ω, and an associated second switch for controlling current through the first resistor; a second resistor having a value measured mΩ so as to be less than that of the first resistor, and an associated third switch for controlling current through the second resistor; a capacitor selectively electrically connectable between the first and second resistors via the second and third switches, respectively; a voltage node, and a voltage divider circuit configured to reduce voltage of the capacitor prior to reaching the voltage node. The system includes an analog-to-digital converter (ADC) electrically connected to the voltage node and a microprocessor circuit, including memory, electrically connected with the sensing circuit and the ADC. The sensing circuit is configured such that 1) when the first switch and the third switch are open, and when the second switch is closed, a pre-charging stage of the capacitor is defined to charge the capacitor to a voltage substantially near the battery voltage V_{b}, while controlling inrush current, with the ADC being configured to obtain voltage value Vs1 associated with the voltage node at the end of the pre-charging stage, 2) after the pre-charging stage and when the first switch and second switch are open, and when the third switch is closed, a second charging stage is defined where the capacitor is charged completely and after a fixed time interval during the second charging stage, the ADC is configured to obtain voltage value Vs2 associated with the voltage node. The microprocessor circuit is configured to compare a measured delta Vs (Vs2−Vs1) to a delta Vs stored in the memory that defines a historical voltage value of a healthy battery, and the microprocessor circuit is configured to identify a change in V_{b} and/or R_{b} when there is a difference between the measured delta Vs and the stored delta Vs and thus identify a SOH of the at least one battery as degraded.

Other objectives, features and characteristics of the present invention, as well as the methods of operation and the functions of the related elements of the structure, the combination of parts and economics of manufacture will become more apparent upon consideration of the following detailed description and appended claims with reference to the accompanying drawings, all of which form a part of this specification.

### BRIEF DESCRIPTION OF THE DRAWINGS

The invention will be better understood from the following detailed description of the preferred embodiments thereof, taken in conjunction with the accompanying drawings, wherein like reference numerals refer to like parts, in which:

FIG. 1 is a schematic view of a vehicle battery and its simplified model circuit.

FIG. 2 is a schematic view of system, in accordance with an embodiment, for monitoring degradation of a battery, connected to a battery and shown during a pre-charging first stage.

FIG. 3 shows the system of FIG. 2 in a second charging stage.

FIG. 4 shows voltage in a ADC vs. time graph in accordance with a low voltage battery embodiment.

FIG. 4A is an enlarged view of the portion encircled in FIG. 4.

FIG. 5 is an enlarged view of voltage in a ADC vs. time graph in accordance with a high voltage battery embodiment.

FIG. 6 shows the system of FIG. 2 in a discharging stage.

FIG. 7 shows the system of FIG. 2 with the sensing circuit disabled, with the battery supplying voltage to all circuits without influence of the sensing circuit.

FIG. 8 is a schematic view of system, in accordance with another embodiment, for monitoring degradation of a battery of a battery pack.

### DETAILED DESCRIPTION OF AN EXEMPLARY EMBODIMENT

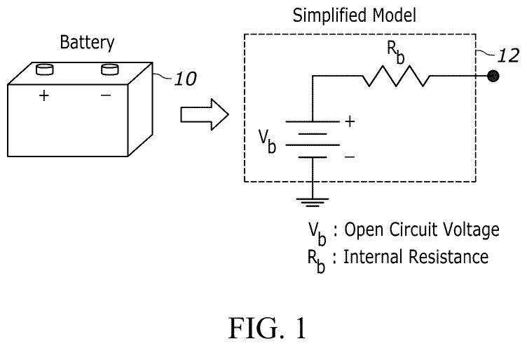

With reference to FIG. 1, schematic view of a battery 10 and its simplified model circuit 12 is shown. The degradation of the battery 10 is a consequence of a degradation of the battery's electrochemical reaction. In terms of electrical parameters, in the embodiment, changes in value of the open circuit voltage V_{b} and/or the internal resistance R_{b} of the battery 10 are employed for monitoring battery SOH. As explained below, measuring these two indicators and comparing them against historical measurements allows for estimating of the degradation in the performance of the battery 10.

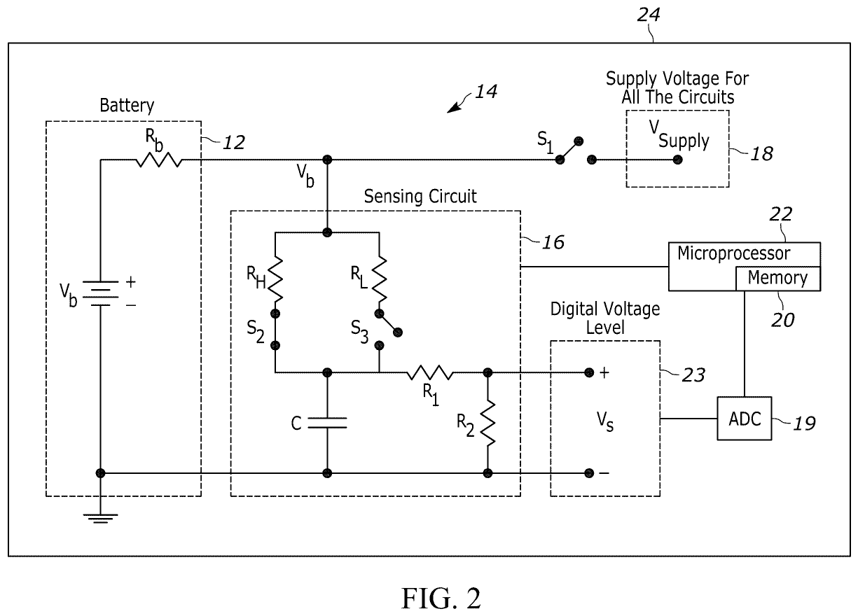

With reference to FIG. 2, in accordance with an embodiment, a system for monitoring degradation of a battery is shown generally indicated at 14. The system 14 includes a sensing circuit structure 16 electrically connected between the battery 12 and a switch S₁. Switch S₁ enables and disables the sensing circuit 14 and connects or isolates the battery 12 from all the circuits 18 that it supplies voltage V_{supply} to, after the drop in the internal resistance R_{b}. The switch S₁ is thus open when measurements are taken from the battery 12 and closed when no measurements are taken.

The sensing circuit 16 includes a high ohmic (having a value measured in ohms) resistor R_{H} in series with switch S₂ and a low ohmic (having a value measured in milli-ohms) resistor R_{L} in series with switch S₃. Each switch S₂ and S₃ is in series with a capacitor C and are used to control two charge stages through the resistors R_{H} and R_{L}, respectively, as explained more fully below. The system 14 also includes divider resistors R₁ and R₂ in series that create a voltage divider circuit used to reduce the voltage in the capacitor C to a lower level so that a analog-to-digital convertor (ADC) 19 can read it. The ADC 19 is connected with digital voltage level node 23 so as to obtain voltage associated therewith. Values of R₁ and R₂ are stored in memory 20 of a microprocessor 22. It is noted that Vₛ is a sensing voltage (voltage of capacitor C) received by the ADC 19. With the system 14, if V_{b} and/or R_{b} change (indicating that the battery 12 is degraded), the amount of electric charge in the capacitor C will change for a fixed time window measurement. The microprocessor 22 can control this time for switches S₂ and S₃ and the microprocessor 22 can compare the values of V_{b} and R_{b} with historical values to determine battery degradation.

With reference to FIG. 2, a first pre-charging stage for the capacitor C is shown that is done with the high ohmic resistor R_{H}. and is used for measuring battery voltage V_{b}. In this first pre-charging stage, S₁ is open, S₂ is closed and S₃ is open. The capacitor C is charged up to a value close to the battery voltage V_{b}. The ADC 19 reads voltage Vₛ, which is the voltage of the capacitor C at voltage node 23. The change in the capacitor C at the end of this first pre-charging stage is achieved by closing the switch S₂ during a time Δt₁ which is a calculated or calibrated value that depends on the elements in the sensing circuit 16. The switch S₂ must be closed approximately 190 ns so that the ADC 19 gets charged up to 3 V at the end of the first pre-charging stage, which will be explained more fully below.

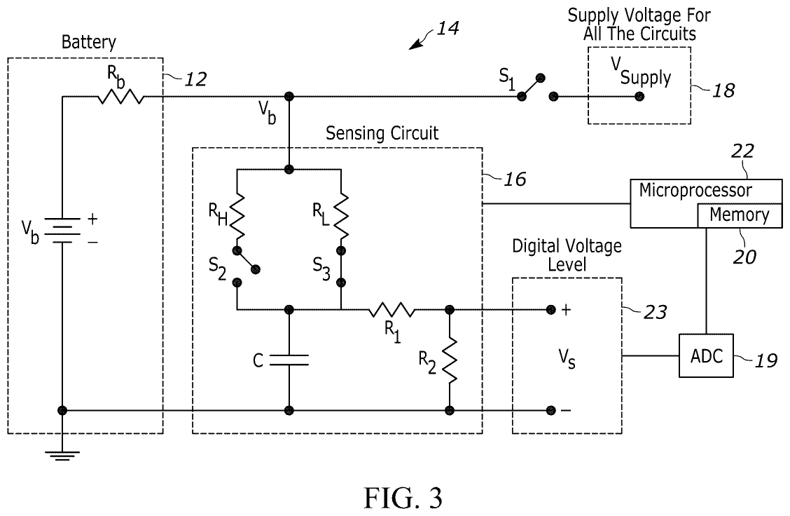

With reference to FIG. 3, a second stage charging for the capacitor C is shown that is done with the low ohmic resistor R_{L} and is used for estimating any change in the internal resistance R_{b} of the battery. In this stage, S₁ is open, S₂ is open and S₃ is closed. In this second stage, the charge in the capacitor C is completed by using a fixed time Δt₂ which is also a calculated or calibrated value. Changes in R_{b} and/or V_{b} will modify the exponential curves that determines how the capacitor C is charged. As explained more fully below, by comparing R_{b} and/or V_{b} to historical measurements stored in the memory 20 of the microprocessor, the degradation of the battery 12 can be determined.

Proper selection of R_{H}, R₁ and R₂ must be taken into account to keep low inrush current (when t=0), the allowable maximum voltage of the ADC 19 must be considered along with the approximate time window in which the measurements of the ADC 19 are to be taken. In an example, a new 12 V (V_{b}) battery which, after a characterization, has a 5 mΩ (R_{b}) of series resistance. The inrush current is calculated by:

$${I}_{Inrush} + \frac{{v}_{b}}{{R}_{b} + {R}_{H}}$$

In the embodiment, the inrush current was limited to 5 A. Thus, R_{H} of 2.4 is calculated by:

$${R}_{H} = \frac{{v}_{b}}{{J}_{inrush}} - {R}_{b}$$

The maximum voltage in the ADC 19 occurs when t→∞. This value must be the maximum allowable voltage for the ADC which can be written as V_{digital}:

$${V}_{digital} = ( \frac{{R}_{2}}{{R}_{b} + {R}_{H} + {R}_{1} + {R}_{2}} ) {v}_{b}$$

Thus, when V_{digital}=3.3 V and R₂ is fixed at 1 kΩ, R₁ is calculated as 2.6 kΩ by:

$${R}_{1} = ( \frac{{v}_{b}}{{v}_{digital}} - 1 ) {R}_{2} - {R}_{b} - {R}_{H}$$

In the example, the value of R_{L} is selected as 50 mΩ (a value in the range of mΩ) so that small changes in R_{b} can be noticed. Because R_{b}+R_{L} is a low ohmic value, high inrush current will be present in the second stage charging. Thus, to reduce this amplitude, the charge level v_{charge1} at the end of the first pre-charging stage (FIG. 2) is calculated by:

$${v}_{charge 1} = \frac{{R}_{1} + {R}_{2}}{{R}_{b} + {R}_{L} + {R}_{1} + {R}_{2}} ( {v}_{b} - ( {R}_{b} + {R}_{L} ) {I}_{inrush} )$$

The maximum current at the beginning of the second stage charging (FIG. 3) is set to 18 A. Thus, at the end of the first pre-charging stage, in the example, the capacitor C will be charged up to v_{charge1}=11 V which is 91.6% of the battery voltage V_{b}. At the end of the first pre-charging stage, the ADC 19 will be charged to 3 V. In the second stage charging, the capacitance so that the ADC 19 reached 3.2 V in 2 ns is calculated as 33 nF by:

$$\begin{matrix}Δ t = 200 ns \\ c = - \frac{Δ t}{{R}_{eq} ln ( \frac{1 - {α}_{2}}{1 - {α}_{1}} )}\end{matrix}$$

For the both the first and second stages of charging, the following equation for a time measurement window Δt is met:

$$Δ t = - τ ln ( \frac{1 - {a}_{2}}{1 - {a}_{1}} )$$

$${R}_{eq} = \frac{( {R}_{b} + {R}_{L} ) ( {R}_{1} + {R}_{2} )}{{R}_{b} + {R}_{L} + {R}_{1} + {R}_{2}}$$

$$where$$

$${a}_{1} = \frac{{V}_{1}}{{V}_{max}}$$

$${a}_{2} = \frac{{V}_{2}}{{V}_{max}}$$

$$τ = {R}_{eq} C$$

Vₘₐₓ=V_{b} for the capacitor C or Vₘₐₓ=V_{digital} for the ADC. V₁ and V₂ are any two voltage values lower than Vₘₐₓ.

Thus, with reference to the above and to FIG. 2, in an example of the embodiment, V_{b}=12 V, R_{b}=5 mΩ, R_{H}=2.4Ω, R_{L}=50 mΩ, C=33 nF, R₁=2.6Ω and R₂=1 kΩ, although other values may be selected.

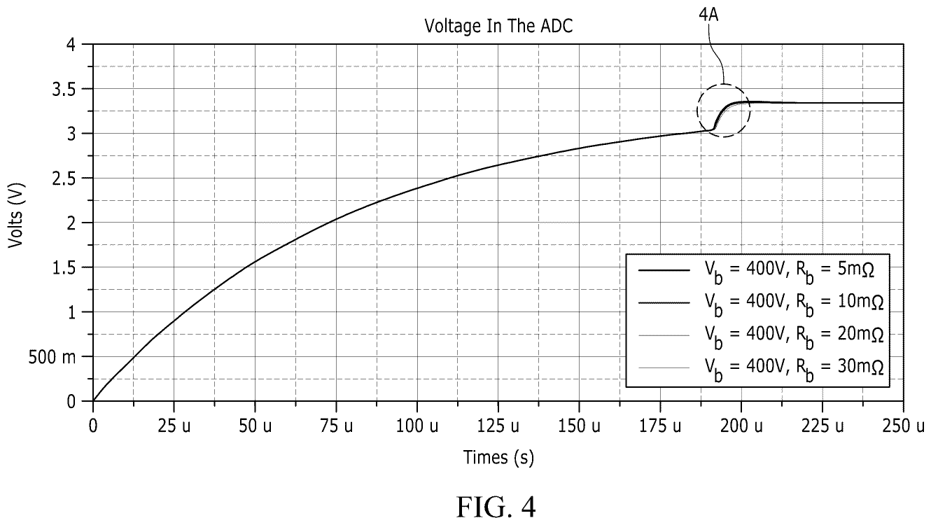

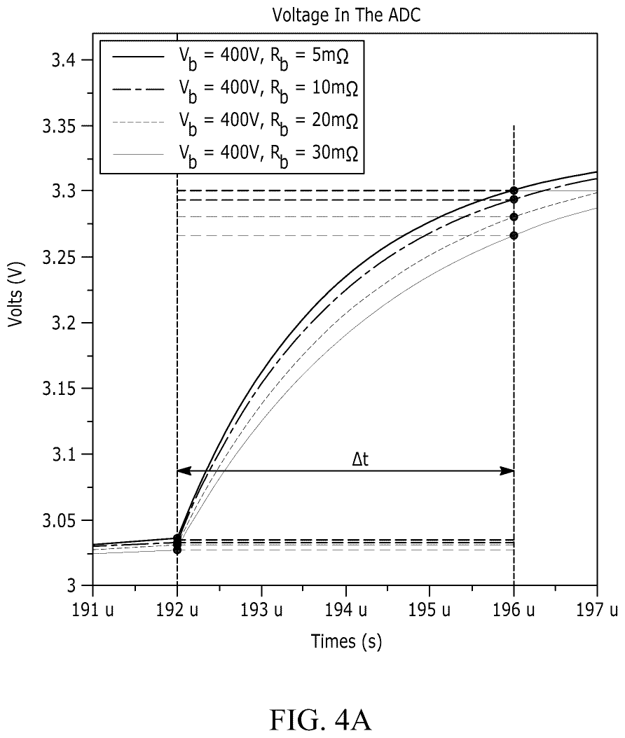

Changes in the resistance of the battery R_{b} results in changes in the charging curve (e.g., FIG. 4) as well. Sampling of the charging voltages in the ADC 19 at specific times can be compared, using the microprocessor 22, with historical measurements of ADC voltages to determine degradation of the battery 12. FIG. 4 is a graph of voltage in the ADC 19 vs. time for a low voltage (e.g., 12 V) battery 12 with R_{b}=5 mΩ as the reference curve. FIG. 4A shows the enlarged portion encircled at 4A in FIG. 4. Thus, as best seen in FIG. 4A, by taking voltage measurements (Vₛ) periodically in a fixed interval Δt, it is possible to identify degradation of the battery 12 by comparing the change in measured voltage (Vₛ) in the ADC 19 to a historical (healthy) change in voltage measurement in a lookup-table stored in memory 20. Differences found in the comparison would indicate degradation. In FIG. 4A, the reference curve is 12 V, R_{b}=5 mΩ V, and FIG. 4A shows three other curves with degraded batteries.

Table 1 shows the three degraded batteries since the delta Vs of these three batteries is different from the delta Vs (265.2 V) of the reference or historical value. These delta Vs measurements must be taken always from the last Vₛ measurement of the first charging stage up to the value reached in Vₛ at the end of the fixed time interval during the second charging stage.

TABLE 1

| Case | Vb | Rb | dt | Vs1 | Vs2 | delta Vs |
|---|---|---|---|---|---|---|
| Reference | 12 V | 5 mOhm | 4 ns | 3.0351 V | 3.3004 V | 265.233 mV |
| Degradation 1 | 12 V | 10 mOhm | 4 ns | 3.0336 V | 3.2935 V | 259.89 mV |
| Degradation 2 | 12 V | 20 mOhm | 4 ns | 3.0307 V | 3.2797 V | 249.049 mV |
| Degradation 3 | 12 V | 30 mohm | 4 ns | 3.0277 V | 3.2661 V | 238.436 mV |

In Table 1, Vs1 is the voltage value in the ADC 19 at the end of the first charging stage. Vs2 is the voltage value in the ADC 19 reached in 4 ns of the second charging stage (4 ns is the fixed interval Δt). The column delta Vs (Vs2−Vs1) shows battery degradation versus a reference. As noted above, for a healthy battery, delta Vs it is expected to measure 265.2 mV always or at least within some small tolerances.

If this battery degrades by increasing its resistance from 5 mOhm to 10 mOhm (degradation case 1), the delta Vs in 4 ns would be now 259.9 mV. When comparing versus the historical measurement, the system 14 would detect a difference of 5.3 mV (V265.2 mV−259.9 mV).

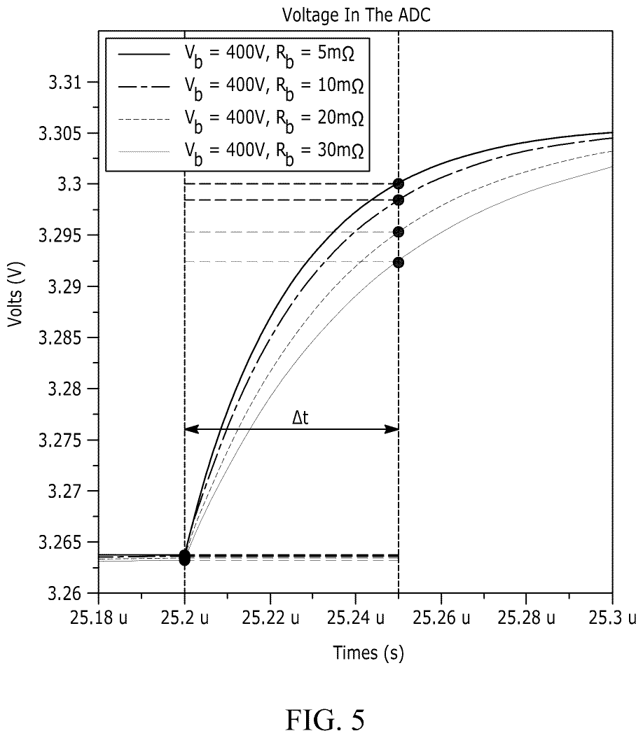

FIG. 5 shows an enlarged portion of a graph of voltage in the ADC 19 vs. time for a high voltage (e.g., 400 V) battery 12 with R_{b}=5 mΩ, R_{H}=8Ω, R_{L}=30 mΩ, C=720 nF, R₁=120 kΩ and R₂=1 kΩ, although other values can be selected. Again, by taking voltage measurements (Vₛ) periodically in a fixed interval Δt, it is possible to identify degradation of the high voltage battery 12 by comparing the measured delta Vs to a historical delta Vs measurement to determine if degradation of the high voltage battery has occurred.

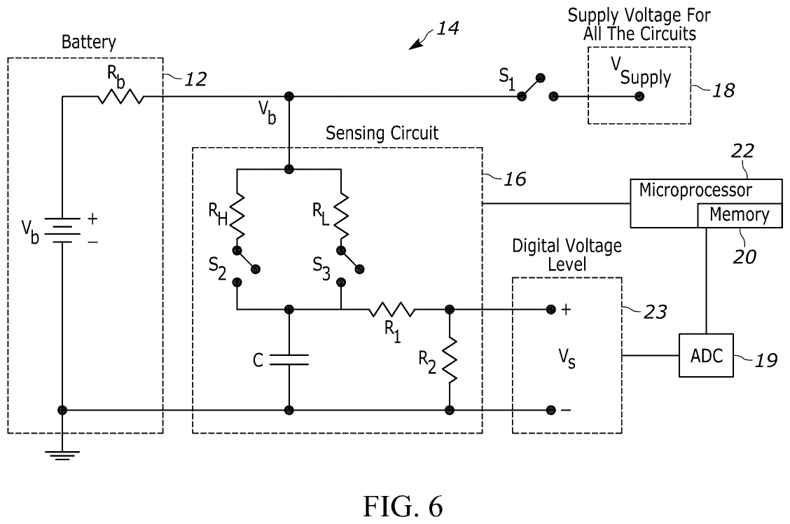

With reference to FIG. 6, a discharge state of the system 14 is shown. In this discharging state, each of switches S₁, S₂ and S₃ is open and the capacitor C will discharge. The voltage in the capacitor C can be measured during the discharge. There is no need to store any value but, the voltage measurement during the discharge can be useful for safety reasons, e.g., as a visual indicator to warn about high voltage levels until safe levels can be reached.

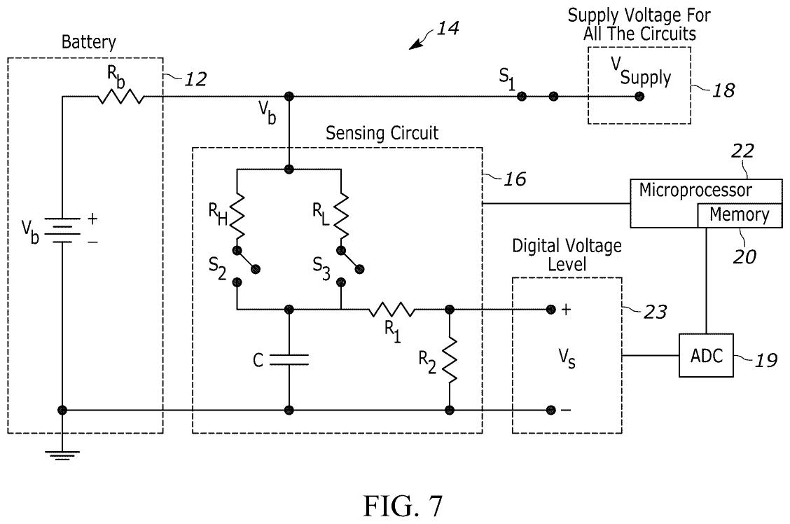

FIG. 7 shows the system 14 when not sensing the SOH of the battery 12. The sensing of the battery SOH with the sensing circuit 16 can be done during startup of the vehicle. After sensing is completed, the battery 12 must supply voltage to all circuits without the influence of the sensing circuit 16. Thus, when, S₂ and S₃ are open and S₁ is closed, the sensing circuit 16 is disabled and the current from the battery 12 flows directly to the circuits to which it is connected.

Thus, the embodiment discloses two charging states of a capacitor as sensing stages using sensing circuit 16, with sampling performed along the second charging curve. In the first or pre-charging stage utilizing higher resistance R_{H}, low inrush current is prioritized to obtain a low delta Vs and then the sensing continues with the second charging stage using a lower resistance R_{L} so as to be more sensitive to low resistance changes. The switches S₂ and S₃ interchange the two reference loads R_{H} and R_{L}, respectively. The high ohmic load R_{H} is used to measure the battery voltage V_{b}. The low ohmic load R_{L} in series with the capacitor C is used to estimate any change in the internal resistance R_{b} of the battery 12.

As noted above, the system 14 is applicable for determining the SOH of both low voltage and high voltage batteries. Although the system 14 and battery 12 is described as being disposed within a vehicle 24 (FIG. 2) so that the testing of the battery 12 can be performed every time the vehicle starts up, it can be appreciated however, that the system can be a stand-alone tester. For a stand-alone tester, switch S₁ and circuits 18 need not be present and the system 14 can be configured to be removably electrically coupled to the battery 12.

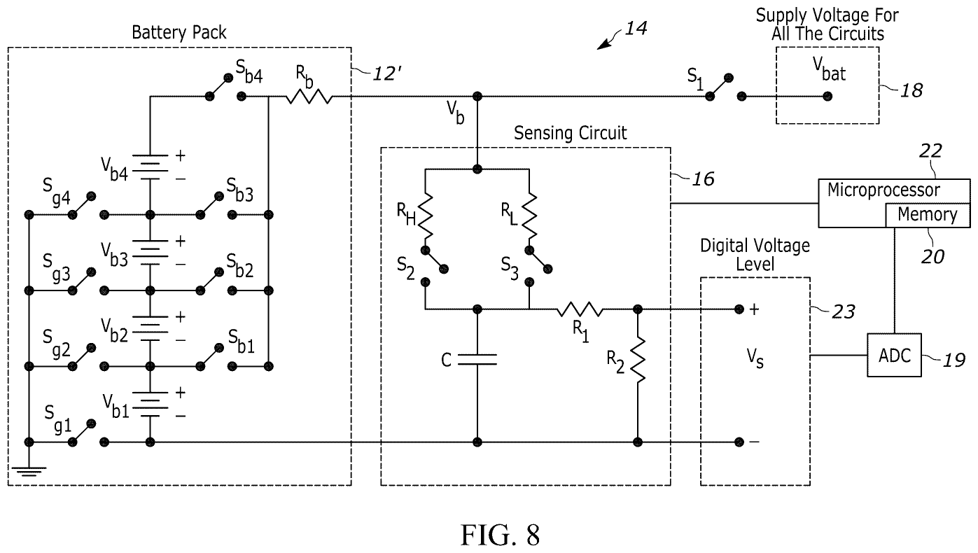

The system 14 is configured for monitoring a single battery 12 at a time. If it is desired to detect degradation of batteries in a pack, it is necessary to test each battery separately to detect the degraded ones. For example, with reference to FIG. 8, a battery pack 12′ of four batteries is shown connected with the system 14 (identical to that described above). To test the first battery having voltage V_{b1}, switch S_{b1} is closed, S_{g1} is closed, and all the other switches in the battery pack 12′ are open and the switches in the sensing circuit 16 can be controlled as described above to perform the testing. Thus, battery V_{b1} is tested separately. To test the second battery having voltage V_{b2} with the sensing circuit 16, switch S_{b2} is closed, S_{g2} is closed, and all the other switches in the battery pack 12′ are open. The other batteries in the battery pack 12′ can be tested separately in a similar manner.

In another embodiment, the switches S_{g1}-S_{g4}, need not be provided and, to test battery V_{b1}, S_{b1} is closed, S_{b2} is open, S_{b3} is open, and S_{b4} is open (Test 1). Another battery can be tested by closing the associated S_{b} switch and opening all other S_{b} switches in the battery pack 12′. If battery V_{b1} is degraded, it will be detected by means of Test 1. If a test of battery V_{b2} indicates degradation, the failure can be because Test 1 fails (which means that battery V_{b1} is damaged), because only battery V_{b2} is degraded (this would mean that Test 1 passed) or because both batteries V_{b1} and V_{b2} are damaged (this would necessarily mean that Test 1 failed). An algorithm executed by the microprocessor 22 could identify the degraded batteries in the battery pack 12′ from the measurements data of the four tests.

The operations and algorithms described herein can be implemented as executable code within the microprocessor circuit 22 as described, or stored on a standalone computer or machine readable non-transitory tangible storage medium that are completed based on execution of the code by a processor circuit implemented using one or more integrated circuits. Example implementations of the disclosed circuits include hardware logic that is implemented in a logic array such as a programmable logic array (PLA), a field programmable gate array (FPGA), or by mask programming of integrated circuits such as an application-specific integrated circuit (ASIC). Any of these circuits also can be implemented using a software-based executable resource that is executed by a corresponding internal processor circuit such as a micro-processor circuit and implemented using one or more integrated circuits, where execution of executable code stored in an internal memory circuit causes the integrated circuit(s) implementing the processor circuit to store application state variables in processor memory, creating an executable application resource (e.g., an application instance) that performs the operations of the circuit as described herein. Hence, use of the term “circuit” in this specification refers to both a hardware-based circuit implemented using one or more integrated circuits and that includes logic for performing the described operations, or a software-based circuit that includes a processor circuit (implemented using one or more integrated circuits), the processor circuit including a reserved portion of processor memory for storage of application state data and application variables that are modified by execution of the executable code by a processor circuit. The memory circuit 20 can be implemented, for example, using a non-volatile memory such as a programmable read only memory (PROM) or an EPROM, and/or a volatile memory such as a DRAM, etc.

The foregoing preferred embodiments have been shown and described for the purposes of illustrating the structural and functional principles of the present invention, as well as illustrating the methods of employing the preferred embodiments and are subject to change without departing from such principles. Therefore, this invention includes all modifications encompassed within the scope of the following claims.

What is claimed is:

1. A method of determining a state of health (SOH) of at least one battery, the at least one battery having a battery voltage (V_{b}) and an internal series resistance (R_{b}), with a first switch between the at least one battery and circuits to be supplied with the battery voltage (V_{b}), the method comprising the steps of:
electrically connecting a sensing circuit between the at least one battery and the first switch, the sensing circuit comprising:
a first resistor having a value measured in Ω, and an associated second switch for controlling current through the first resistor,
a second resistor having a value measured mΩ so as to be less than that of the first resistor, and an associated third switch for controlling current through the second resistor,
a capacitor selectively electrically connectable between the first and second resistors via the first and second switches, respectively,
a voltage node, and
a voltage divider circuit configured to reduce voltage of the capacitor prior to reaching the voltage node,
ensuring that the first switch and third switch are open, and that the second switch is closed to define a pre-charging stage of the capacitor to charge the capacitor to a voltage substantially near the battery voltage V_{b}, while controlling inrush current,
at the end of the pre-charging stage, obtaining voltage value Vs1 associated with the voltage node,
after the pre-charging stage, ensuring that the first switch and second switch are open, and that the third switch is closed to define second charging stage where the capacitor is charged completely,
after a fixed time interval during the second charging stage, obtaining voltage value Vs2 associated with the voltage node,
comparing a measured delta Vs (Vs2−Vs1) to a delta Vs that defines a stored historical voltage value of a healthy battery, and
identifying a change in V_{b} and/or R_{b} when there is a difference between the measured delta Vs and the stored delta Vs and thus identifying a SOH of the at least one battery as degraded.

2. The method of claim 1, wherein the battery, the first switch and the sensing system are disposed on a vehicle, and wherein the pre-charging stage and the second charging stage are performed upon startup of the vehicle.

3. The method of claim 1, further comprising:
after the second charging stage, ensuring that the first switch, second and third switch are each open to define a capacitor discharging stage.

4. The method of claim 1, further comprising:
after the comparing step, ensuring that the first switch is closed, the second and third switch are each open, to disable the sensing circuit and thus permit the battery to supply voltage (V_{b}) to the circuits to which it is connected.

5. The method of claim 1, wherein the voltage divider circuit is provided as two divider resistors in series.

6. The method of claim 1, further comprising an analog-to-digital converter (ADC) electrically connected to the voltage node, the method including reading the voltages Vs2 and Vs1 by the ADC.

7. The method of claim 2, wherein the battery voltage (V_{b}) is 12 V and the internal series resistance (R_{b}) is 5 mΩ, and wherein the resistance of the first resistor is provided as 2.4Ω, a resistance of the second resistor is provided as 50 mΩ, and the capacitance of the capacitor is provided as 33 nF.

8. The method of claim 2, wherein the battery voltage (V_{b}) is 400 V and the internal series resistance (R_{b}) is 5 mΩ, and wherein the resistance of the first resistor is provided as 8Ω, a resistance of the second resistor is provided as 30 mΩ, and the capacitance of the capacitor is provided as 720 nF.

9. The method of claim 1, wherein the fixed time interval is 4 ns.

10. The method of claim 1, wherein a plurality of batteries are provided in a battery pack and the method includes separately identifying the SOH of each battery in the battery pack.

11. A system for monitoring a state of health (SOH) of at least one battery, the at least one battery having a battery voltage (V_{b}) and an internal series resistance (R_{b}), with a first switch between the at least one battery and circuits to be supplied with the battery voltage (V_{b}), the system comprising:
a sensing circuit between the battery and the first switch, the sensing circuit comprising:
a first resistor having a value measured in Ω, and an associated second switch for controlling current through the first resistor,
a second resistor having a value measured mΩ so as to be less than that of the first resistor, and an associated third switch for controlling current through the second resistor,
a capacitor selectively electrically connectable between the first and second resistors via the second and third switches, respectively,
a voltage node, and
a voltage divider circuit configured to reduce voltage of the capacitor prior to reaching the voltage node,
an analog-to-digital converter (ADC) electrically connected to the voltage node, and
a microprocessor circuit, including memory, electrically connected with the sensing circuit and the ADC,
wherein the sensing circuit is configured such that 1) when the first switch and the third switch are open, and when the second switch is closed, a pre-charging stage of the capacitor is defined to charge the capacitor to a voltage substantially near the battery voltage V_{b}, while controlling inrush current, with the ADC being configured to obtain voltage value Vs1 associated with the voltage node at the end of the pre-charging stage, 2) after the pre-charging stage and when the first switch and the second switch are open, and when the third switch is closed, a second charging stage is defined where the capacitor is charged completely and after a fixed time interval during the second charging stage, the ADC is configured to read voltage value Vs2 associated with the voltage node,
wherein the microprocessor circuit is configured to compare a measured delta Vs (Vs2−Vs1) to a delta Vs stored in the memory that defines a historical voltage value of a healthy battery, and the microprocessor circuit is configured to identify a change in V_{b} and/or R_{b} when there is a difference between the measured delta Vs and the stored delta Vs and thus identify a SOH of the at least one battery as degraded.

12. The system of claim 11, in combination with the at least one battery and the first switch, wherein the at least one battery, the first switch and the system are disposed on a vehicle.

13. The system of claim 12, wherein the at least one battery is a battery pack including a plurality of batteries.

14. The system of claim 11, wherein the voltage divider circuit includes two divider resistors in series.

15. The system of claim 12, wherein the battery voltage (V_{b}) is 12 V and the internal series resistance (R_{b}) is 5 mΩ, and wherein the resistance of the first resistor is provided as 2.4Ω, a resistance of the second resistor is provided as 50 mΩ, and the capacitance of the capacitor is provided as 33 nF.

16. The system of claim 12, wherein the battery voltage (V_{b}) is 400 V and the internal series resistance (R_{b}) is 5 mΩ, and wherein the resistance of the first resistor is provided as 8Ω, a resistance of the second resistor is provided as 30 mΩ, and the capacitance of the capacitor is provided as 720 nF.

17. A system for monitoring a state of health (SOH) of at least one battery, the at least one battery having a battery voltage (V_{b}) and an internal series resistance (R_{b}), the system comprising:
a sensing circuit, electrically connectable to the at least one battery, comprising:
a first resistor having a value measured in Ω, and an associated first switch for controlling current through the first resistor,
a second resistor having a value measured mΩ so as to be less than that of the first resistor, and an associated second switch for controlling current through the second resistor,
a capacitor selectively electrically connectable between the first and second resistors via the first and second switches, respectively,
a voltage node, and
a voltage divider circuit configured to reduce voltage of the capacitor prior to reaching the voltage node,
an analog-to-digital converter (ADC) electrically connected to the voltage node, and
a microprocessor circuit, including memory, electrically connected with the sensing circuit and the ADC,
wherein the sensing circuit is configured such that 1) when the second switch is open and the first switch is closed, a pre-charging stage of the capacitor is defined to charge the capacitor to a voltage substantially near the battery voltage V_{b}, while controlling inrush current, with the ADC being configured to obtain voltage value Vs1 associated with the voltage node at the end of the pre-charging stage, 2) after the pre-charging stage and when the first switch is open and the second switch is closed, a second charging stage is defined where the capacitor is charged completely and after a fixed time interval during the second charging stage, the ADC is configured to read voltage value Vs2 associated with the voltage node,
wherein the microprocessor circuit is configured to compare a measured delta Vs (Vs2−Vs1) to a delta Vs stored in the memory that defines a historical voltage value of a healthy battery, and the microprocessor circuit is configured to identify a change in V_{b} and/or R_{b} when there is a difference between the measured delta Vs and the stored delta Vs and thus identify a SOH of the at least one battery as degraded.

18. The system of claim 17, wherein the system is a stand-alone system configured to be removably electrically connected with the at least one battery.
